(19) United States
(12) Patent Application Publication
(10) Pub. No.: US 2008/0061334 A1
(43) Pub. Date: Mar. 13, 2008

(54) Semiconductor memory device and method for forming the same

(75) Inventors: Ju-Young Jung, Seoul (KR); Suk-Ho Joo, Seoul (KR); Jung-Hoon Park, Seoul (KR); Heung-Jin Joo, Suwon-si (KR); Hee-San Kim, Seoul (KR); Seung-Kuk Kang, Suwon-si (KR); Do-Yeon Choi, Seoul (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/896,952

(22) Filed: Sep. 7, 2007

(30) Foreign Application Priority Data
Sep. 7, 2006 (KR) 10-2006-86353

(51) Int. Cl. H01L 29/94; H01L 21/02

(52) U.S. Cl. 257/295; 438/3; 257/E29.345; 257/E21.008

(57) ABSTRACT

A semiconductor memory device and a method for forming the same. The method includes forming an insulating layer on a semiconductor substrate having a conductive region, forming a contact hole that exposes the conductive region by etching the insulating layer, forming a barrier metal layer that covers a sidewall and a bottom of the contact hole, and forming a contact plug in the contact hole by interposing the barrier metal layer therebetween. An etching process may be preformed that recesses the barrier metal layer and the contact plug in such a manner that a top surface of the contact plug protrudes upward beyond a top surface of the barrier metal layer. A capping plug may be formed covering the recessed barrier metal layer and the recessed contact plug. A capacitor may be formed on the capping plug.

### PRIORITY STATEMENT

This U.S. non-provisional patent application claims the benefit of priority under 35 U.S.C. §119 of Korean Patent Application No. 2006-86353, filed on Sep. 7, 2006, the entire contents of which are hereby incorporated by reference.

### BACKGROUND

1. Field

Example embodiments disclosed herein relate to a semiconductor memory device. Other example embodiments relate to a ferroelectric random access memory (FRAM) device and a method for forming the same.

2. Description of Related Art

In general, semiconductor memory devices may be classified as volatile or nonvolatile memory devices. Volatile memory devices may lose stored information when the power applied to the device is removed. Nonvolatile memory devices continuously retain stored information even if the power applied to the device is removed.

A ferroelectric random access memory (FRAM) device is a type of nonvolatile memory device. A FRAM device uses a ferroelectric material (e.g., (Sr, Bi)Ta₂O₉ (SBT) or Pb(Zr, Ti) O₃ (PZT)) as a capacitor dielectric. Electrodes may be formed at opposite sides of a ferroelectric thin film. The electrodes may include noble metals (e.g., platinum (Pt), ruthenium (Ru), iridium (Ir) and oxides and combinations thereof. The FRAM device retains data even if power applied thereto is removed. FRAM devices have an operational speed corresponding to that of a dynamic random access memory (DRAM) device.

The ferroelectric material used as the capacitor dielectric may exhibit reactive characteristics such that the ferroelectric material should not be subjected to certain reactions in the process of forming the capacitor. Because a contact plug, which is formed prior to the capacitor, includes tungsten which exhibits substantially strong reactive characteristics relative to the ferroelectric material, the contact plug may degrade the characteristics of the ferroelectric thin film. As such, reliability and operational characteristics of the FRAM device may also be degraded.

### SUMMARY

Example embodiments disclosed herein relate to a semiconductor memory device. Other example embodiments relate to a ferroelectric random access memory (FRAM) device and a method for forming the same.

Example embodiments provide a semiconductor memory device capable of increasing reliability and/or operational characteristics thereof and a method for forming the same.

According to example embodiments, the semiconductor memory device includes a semiconductor substrate having a conductive region, an insulating layer having a contact hole that exposes the conductive region on the substrate and a contact plug in the contact hole. A barrier metal layer may be formed on a sidewall and a bottom wall of the contact plug. A capping plug may be formed on the barrier metal layer. The capping plug may include a first portion contacting with a top surface of the contact plug and a second portion interposed between the first portion and a sidewall of the contact hole while extending downward below the top surface of the contact plug. A capacitor may be formed on the capping plug.

According to example embodiments, the top surface of the contact plug may protrude upward beyond a top surface of the barrier metal layer. The second portion of the capping plug may contact the barrier metal layer at a sidewall of the contact plug. The capping plug may have a top surface on a same, or substantially the same, level with a top surface of the insulating layer.

According to example embodiments, the capacitor may include a bottom electrode, a ferroelectric layer pattern and a top electrode.

According to example embodiments, the method of forming a semiconductor memory device includes forming an insulating layer on a semiconductor substrate having a conductive region, forming a contact hole that exposes the conductive region by etching the insulating layer and forming a barrier metal layer that covers a sidewall and a bottom of the contact hole. A contact plug may be formed in the contact hole by interposing (or forming) the barrier metal layer between the contact plug and the contact hole. An etching process may be performed to recess the barrier metal layer and the contact plug in such a manner that a top surface of the contact plug protrudes upward beyond a top surface of the barrier metal layer. A capping plug may be formed that covers the recessed barrier metal layer and the recessed contact plug. A capacitor may be formed on the capping plug.

According to example embodiments, the etching process may be performed based on an etching condition in which an etching rate of the barrier metal layer is greater than an etching rate of the contact plug. An etching selectivity of the metal barrier layer relative with respect to the contact plug may be about 1.0 to about 1.7.

According to example embodiments, the capping plug has a top surface on a same, or substantially the same, level with a top surface of the insulating layer.

According to example embodiments, forming the capacitor may include sequentially forming an adhesive layer, a buffer layer, a bottom electrode layer, a ferroelectric layer and a top electrode layer on the semiconductor substrate having the capping plug and patterning top electrode layer, the ferroelectric layer, the bottom electrode layer, the buffer layer and the adhesive layer.

### BRIEF DESCRIPTION OF THE FIGURES

Example embodiments will be more clearly understood from the following detailed description taken in conjunction with the accompanying drawings. FIGS. 1-9 represent non-limiting, example embodiments as described herein.

FIG. 1 is a diagram illustrating a schematic sectional view of an FRAM device according to example embodiments; and

FIGS. 2 through 9 are diagrams illustrating sectional views of a method for forming an FRAM device according to example embodiments.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements-present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments disclosed herein relate to a semiconductor memory device. Other example embodiments relate to a ferroelectric random access memory (FRAM) device and a method for forming the same.

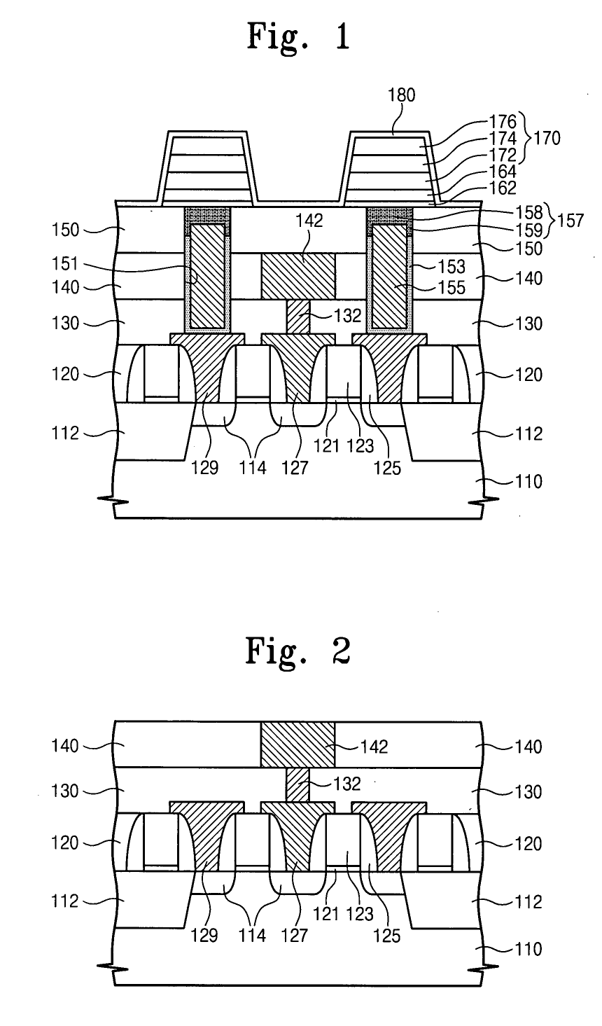

FIG. 1 is a diagram illustrating a schematic sectional view of an FRAM device according to example embodiments.

Referring to FIG. 1, gate electrodes 123 may be positioned (or formed) on an active region (not shown). The active region may be determined by an isolation region 112 formed on a semiconductor substrate 110. Gate insulating layers 121 may be interposed between the active region and the gate electrodes 123. The gate electrodes 123 may include a conductive pattern (not shown) and a hard mask pattern (not shown). Impurity regions 114 may be formed in the active area at both sides of the gate electrodes 123. The impurity regions 114 may function as a source region or a drain region. Spacers 125 may be positioned at both sidewalls of the gate electrodes 123. A first insulating layer 120 may be formed between the gate electrodes 123. The first insulating layer 120 includes a top surface having a height identical to that of the gate electrode 123.

First and second contact pads 127 and 129 may be formed on (or over) the impurity areas 114. The first and second contact pads 127 and 129 may contact the impurity areas 114 by passing through the first insulating layer 120. The first and second contact pads 127 and 129 may be self-aligned on the spacers 125. Second and third insulating layers 130 and 140 may be positioned (or formed) on (or over) each of the first and second contact pads 127 and 129. A conductive line 142 may be disposed (or formed) in the third insulating layer 140. A conductive pattern 132 may be disposed (or formed) in the second insulating layer 130 so as to electrically connect the first contact pad 127 with the conductive line 142. The conductive line 142 may be a bit line or a data line. A fourth insulating layer 150 may be disposed (or formed) on the conductive line 142.

A contact plug 155 may be disposed (or formed) on the second contact pad 129. The contact plug 155 may pass through the second, third and fourth insulating layers 130, 140 and 150 to be connected electrically to the second contact pad 129. Barrier metal layers 153 may be disposed (or formed) at the sidewall and the bottom wall of the contact plug 155. The top surface of the contact plug 155 may be higher than the top surface of the barrier metal layer 153. The top surface of the contact plug 155 protrudes upward beyond the top surface of the barrier metal layer 153.

A capping plug 157 may be formed on the contact plug 155 and the barrier metal layer 153. The capping plug 157 includes a first portion 158 and a second portion 159. The first portion 158 contacts the top surface of the contact plug 155. The second portion 159 extends downward from the sidewall of the first portion 158 below the top surface of the contact plug 155. The second portion 159 of the capping plug 157 contacts the barrier metal layer 153 at the sidewall of the contact plug 155. The capping plug 157 has a top surface corresponding to the top surface of the fourth insulating layer 150.

An adhesive layer 162, a buffer layer 164 and a capacitor 170 may be sequentially formed on the capping plug 157. The capacitor 170 includes a bottom electrode 172, a ferroelectric layer 174 and a top electrode 176. The adhesive layer 162 and the buffer layer 164 function to bond and dampen the bottom electrode 172. The adhesive layer 162 and the buffer layer 164 function as a barrier metal layer. A protective layer 180 may be formed on the semiconductor substrate to cover the capacitor 170. The protective layer 180 prevents gas (e.g., oxygen or hydrogen) from penetrating into the ferroelectric layer 174, preventing characteristics of the ferroelectric layer 174 from being degraded.

According to example embodiments, the capping plug 157 covers the top surface of the contact plug 155 and an upper sidewall of the contact plug 155 that protrudes upward beyond the barrier metal layer 153. The capping plug 157 prevents the contact plug 155 from being exposed between the fourth insulating layers 150, preventing the contact plug 155 from being damaged in the process of forming the capacitor 170.

FIGS. 2 through 9 are diagrams illustrating sectional views of a method for forming an FRAM device according to example embodiments.

Referring to FIG. 2, the isolation layers 112 that define the active area may be formed on the semiconductor substrate 110. The gate insulating layers 121 and the gate electrodes 123 may be formed on the active area. The gate electrode 123 may have a stack structure including the conductive pattern (not shown) and the hard mask pattern (not shown). Impurity areas 114 that function as source/drain areas may be formed on the active area at both sides of the gate electrode 123. The spacers 125 may be formed at both sidewalls of the gate electrode 123.

The first insulating layer 120 may be formed on the semiconductor substrate. The first insulating layer 120 has the top surface having an identical height to that of the gate electrode 123. The first and second contact pads 129 may be formed on the semiconductor substrate contacting the impurity regions 114 by passing through the first insulating layer 120. The first and second contact pads 127 and 129 may include conductive materials. The first and second contact pads 127 and 129 may be self-aligned on the spacers 125.

The second and third insulating layers 130 and 140 may be formed on the semiconductor substrate with the first and second contact pads 127 and 129. The conductive line 142 may be formed in the third insulating layer 140. The conductive pattern 132 may be formed in the second insulating layer 130 in order to electrically connect the conductive line 142 with the first contact pad 127. The conductive line 142 and the conductive pattern 132 may be formed through the damascene process.

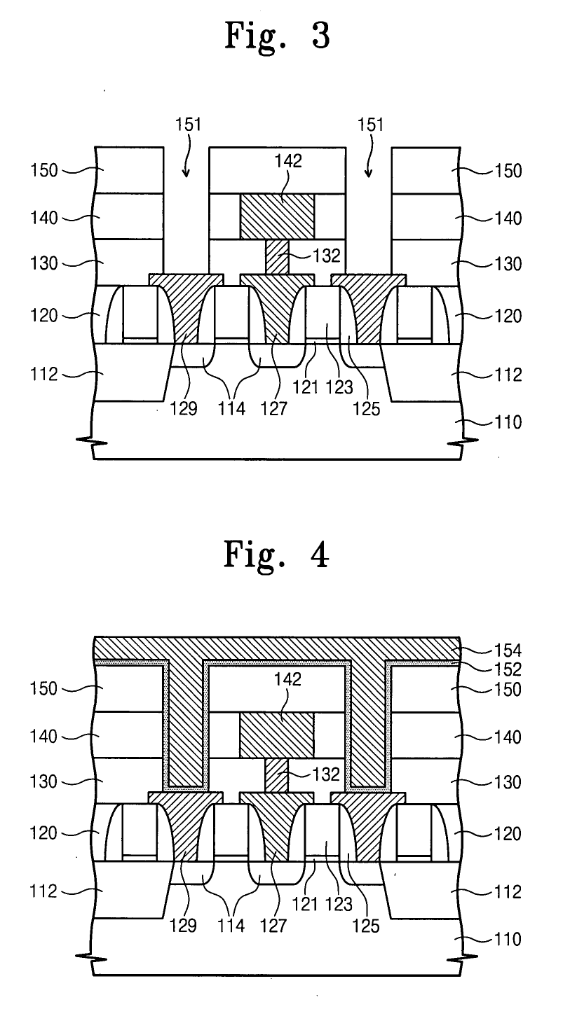

Referring to FIG. 3, the fourth insulating layer 150 may be formed on the third insulating layer 140 including the conductive line 142. The second, third and fourth insulating layers 130, 140 and 150 may be patterned to form contact holes 151 through which the second contact pads 129 are exposed.

Referring to FIG. 4, first and second metal layers 152 and 154 may be formed on the semiconductor substrate having the contact holes 151. The first metal layer 152 extends along the sidewall and the bottom of the contact holes 151 and the top surface of the fourth insulating layer 150. The contact holes 151 may be filled with the second metal layer 154. The first metal layer 152 may include titanium (Ti), titanium nitride (TiN), tantalum (Ta) or tantalum nitride (TaN). The second metal layer 154 includes tungsten (W).

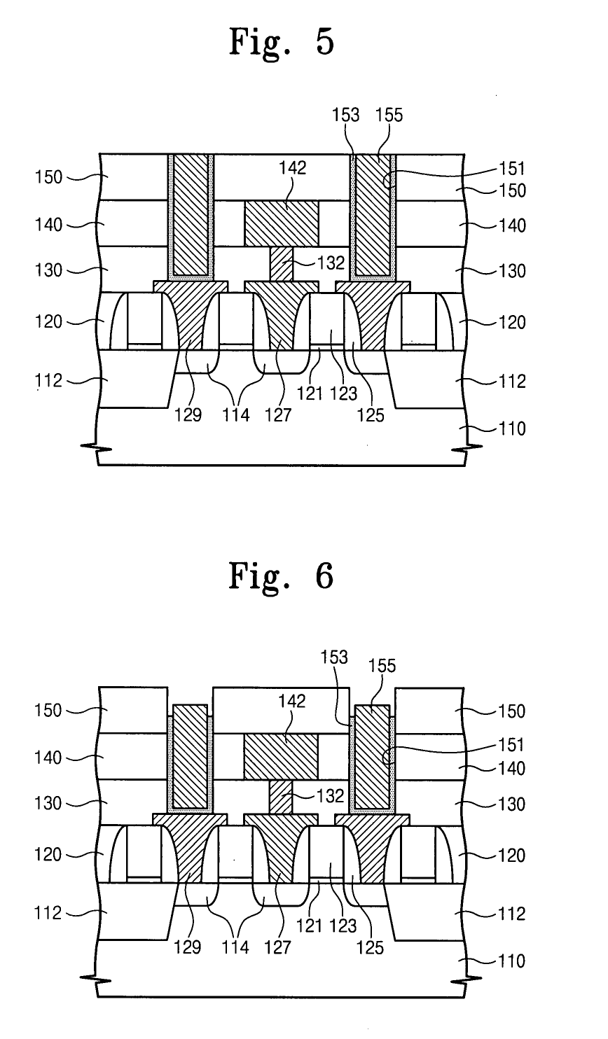

Referring to FIG. 5, a planar process may be performed to expose the fourth insulating layer 150 and to form the contact plug 155 and the barrier metal layer 153 in the contact holes 151. The contact plug 155 and the barrier metal layer 153 have top surfaces on a same, or substantially the same, level with the top surface of the fourth insulating layer 150. Due to the etching selectivity between the contact plug 155 and the fourth insulating layer 150, the top surface of the contact plug 155 may have a convex shape or a concave shape.

Referring to FIG. 6, the contact plug 155 and the barrier metal layer 153 may be recessed through an etching process. The etching process may be performed based on a desired etching condition in which the etching rate of the barrier metal layer 153 is greater than that of the contact plug 155. The recessed contact plug 155 protrudes upward beyond the top surface of the recessed barrier metal layer 153.

The etching selectivity of the barrier metal layer 153 with respect to the contact plug 155 may be about 1 to about 1.7. If the etching selectivity is less than 1, the contact plug 155 may be etched more than the barrier metal layer 153 such that the contact plug 155 does not protrude above the barrier metal layer 153. If the etching selectivity is greater than 1.7, the barrier metal layer 153 may be excessively etched as compared to the contact plug 155 such the metal layer is not uniformly formed between the recessed contact plug 151 and the sidewall of the contact hole 151 in the subsequent processes.

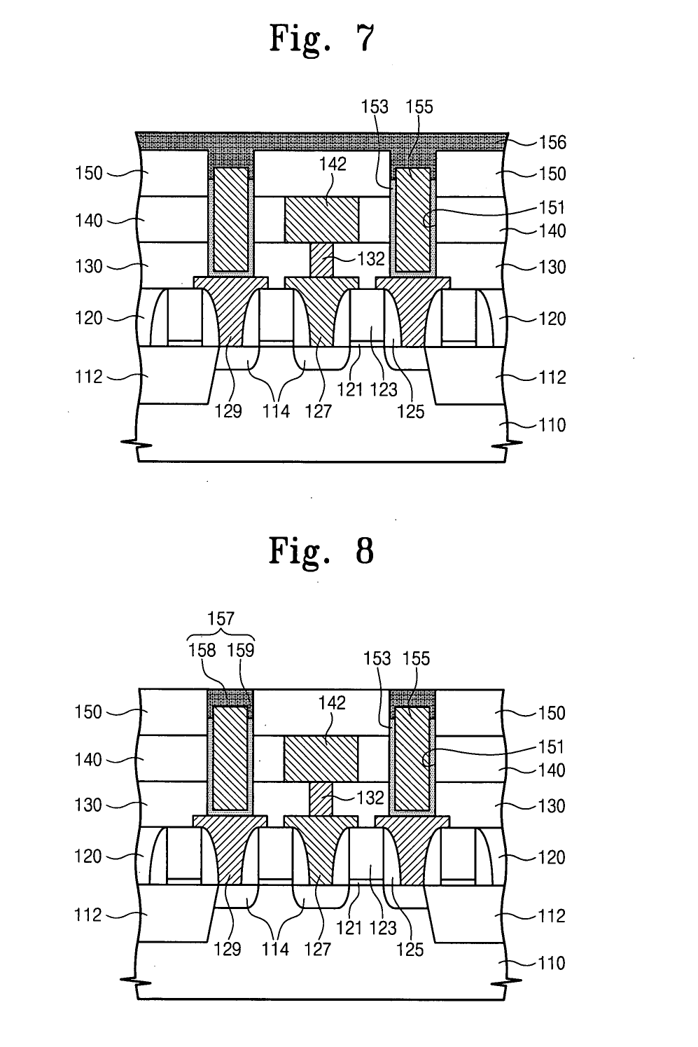

Referring to FIGS. 7 and 8, the third metal layer 156 may be formed on the semiconductor substrate. The third metal layer 156 includes TiN. The planar process may be performed such that the top surface of the fourth insulating layer 150 is exposed and the capping plug 157 is formed in the contact hole 151. The capping plug 157 has the top surface corresponding to that of the fourth insulating layer 150. The contact plug 157 includes the first and second sections 158 and 159. The first section 158 makes contact with the top surface of the contact plug 155. The second section 159 may be interposed between the first section 158 and the sidewall of the contact hole 151 while extending downward below the top surface of the contact plug 155.

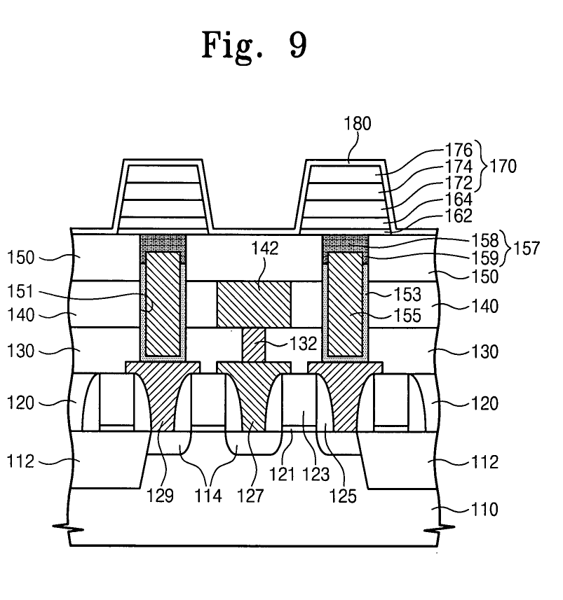

Referring to FIG. 9, the adhesive layer 162, the buffer layer 164 and the capacitor 170 may be sequentially formed on the capping plug 157. The capacitor 170 includes the bottom electrode 172, the ferroelectric layer 174 and the top electrode 176. The adhesive layer 162 may include Ti. The buffer layer 164 may include TiAlN. The bottom electrode 172 and the top electrode 176 may include iridium (Ir). The ferroelectric layer 174 may include a ferroelectric material (e.g., PZT). The protective layer 180 may be formed on the semiconductor substrate having the capacitor 170. The protective layer may include Al₂O₃ or SiON.

According to example embodiments, the recessed contact plug 155 may protrude above the top surface of the recessed barrier metal layer 153 by performing the etching process. The etching process may be determined based on the etching selectivity between the contact plug 155 and the barrier metal layer 153. The capping layer 157 that covers the top surface of the contact plug 155 and the upper sidewall of the contact plug 155, which protrudes upward beyond the top surface of the barrier metal layer 153, may be formed through an easier process. Because the contact plug 155 is etched simultaneously with the barrier metal layer 153, metallic materials of the contact plug 155 may not remain at the sidewall of the contact hole 151. The capping plug 157 prevents (or reduces) exposure of the contact plug 155 between the fourth insulating layers 150, preventing (or reducing the likelihood of) the contact plug 155 from being damaged in the process of forming the capacitor 170.

According to example embodiments, the contact plug may be stably formed without being damaged. Reliability and operational characteristics of the semiconductor memory device may increase.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of forming a semiconductor memory device, the method comprising:
forming an insulating layer on a semiconductor substrate, the insulating layer having a conductive region;
forming a contact hole that exposes the conductive region by etching the insulating layer;
forming a barrier metal layer that covers a sidewall and a bottom of the contact hole;
forming a contact plug in the contact hole by interposing the barrier metal layer between the contact plug and the contact hole;
performing an etching process that recesses the barrier metal layer and the contact plug in such a manner that a top surface of the contact plug protrudes upward beyond a top surface of the barrier metal layer;
forming a capping plug that covers the recessed barrier metal layer and the recessed contact plug; and
forming a capacitor on the capping plug.

2. The method of claim 1, wherein an etching rate of the barrier metal layer is greater than an etching rate of the contact plug.

3. The method of claim 2, wherein an etching selectivity of the barrier metal layer relative with respect to the contact plug is about 1.0 to about 1.7.

4. The method of claim 1, wherein a top surface of the capping plug and a top surface of the insulating layer are on a same level.

5. The method of claim 1, wherein forming the capacitor includes:
sequentially forming a bottom electrode layer, a ferroelectric layer and a top electrode layer on the semiconductor substrate having the capping plug; and
patterning the top electrode layer, the ferroelectric layer and the bottom electrode layer.

6. The method of claim 1, wherein forming the capacitor includes:
sequentially forming an adhesive layer, a buffer layer, a bottom electrode layer, a ferroelectric layer and a top electrode layer on the semiconductor substrate having the capping plug; and
patterning the top electrode layer, the ferroelectric layer, the bottom electrode layer, the buffer layer and the adhesive layer.

7. The method of claim 1, wherein forming the capping layer includes forming a capping layer having a first portion and a second portion, wherein the first portion contacts the top surface of the contact plug and the second portion is interposed between the first portion and the sidewall of the contact hole, the second portion extending downward below the top surface of the contact plug.

8. The method of claim 7, wherein the second portion of the capping plug contacts the barrier metal layer at the sidewall the recessed contact plug.

9. The method of claim 1, wherein the semiconductor memory device is a ferroelectric random access memory (FRAM) device.

10. A semiconductor memory device, comprising:
a semiconductor substrate having a conductive region;
an insulating layer having a contact hole that exposes the conductive region on the substrate;
a contact plug in the contact hole;
a barrier metal layer on a sidewall and a bottom wall of the contact plug;
a capping plug including a first portion contacting a top surface of the contact plug and a second portion interposed between the first portion and a sidewall of the contact hole, wherein the second portion extends downward below the top surface of the contact plug; and
a capacitor on the capping plug.

11. The semiconductor memory device of claim 10, wherein the top surface of the contact plug protrudes upward beyond a top surface of the barrier metal layer.

12. The semiconductor memory device of claim 10, wherein the second portion of the capping plug contacts with the barrier metal layer at a sidewall of the contact plug.

13. The semiconductor memory device of claim 10, wherein a top surface of the capping plug and a top surface of the insulating layer are on a same level.

14. The semiconductor memory device of claim 10, wherein the capacitor includes a bottom electrode, a ferroelectric layer pattern and a top electrode.

15. The semiconductor memory device of claim 14, wherein the capacitor includes an adhesive layer and a buffer layer sequentially formed below the bottom electrode.

16. The semiconductor memory device of claim 10, wherein the barrier metal layer has a greater etching rate than the contact plug.

17. The semiconductor memory device of claim 16, wherein an etch selectivity of the barrier metal layer relative with respect to the contact plug is about 1.0 to about 1.7.
